(19) United States
(12) Patent Application Publication
(10) Pub. No.: US 2009/0096462 A1
(43) Pub. Date: Apr. 16, 2009

(54) Wafer testing method

(76) Inventors: Bily Wang, Hsinchu City (TW); Hsin-Cheng Chen, Jhudong Township (TW); Ming-Hao Chou, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/010,119

(22) Filed: Jan. 22, 2008

(30) Foreign Application Priority Data
Oct. 12, 2007 (TW) 96138199

(51) Int. Cl. G01R 31/26

(52) U.S. Cl. 324/501

(57) ABSTRACT

A wafer testing method for wafer testing system comprises the steps: loading a wafer and then positioning the wafer relatively to a map file image stored in a map file. The map file is of a first file type. The next step is inspecting the appearance of the wafer. When the user detects defects on the wafer, the positions of the defects are directly recorded in the map file and then the modified map file is saved. The map file can be directly modified when the wafer is in the testing procedure so that the testing time is reduced. Furthermore, the precision of the testing is improved.

### BACKGROUND OF THE INVENTION

1. Field of the Invention

The present invention relates to a wafer testing method and in particular to a wafer testing system provided for modifying the inspection result in a map file.

2. Description of Prior Art

The semiconductor industry is increasingly developed because personal mobile communication, electronic commercial business, global communication and digital home appliances are used in modern life. In the production of semiconductors, the main focus is on throughput rate and product yield.

Some processes work directly on the semiconductor substrate, such as metal deposition, lithograph for patterning, and ion implantation so that an integrated circuit is formed on the substrate. To ensure that the circuitry is fully functional, electrical testers test the substrates after certain key processes. For example, after a metal deposition step is performed, it is determined whether the depth of the metal layer exceeds a threshold level or whether crystallization of the metal occurred.

After the substrate has gone through all the required processing steps, comprehensive electric tests are performed on each die to ensure that the circuitry is functional. This stage is sometimes called the wafer sort stage, and bad dies are classified from good dies based on the results of the electric tests by inking the bad dies. The employed tests generally use electric measurements, and the results of the tests are saved and outputted in an electronic file, i.e. a computer file. In the final packaging step, the dies are packaged, except for the bad dies in order to save packaging material. After the electrical tests, the operator visually inspects individual dies and writes the results on paper, typically run-cards, shipping papers, and others. This visual test is performed for determining to see if scratches or defects are formed on the wafer surface.

In the conventional technique for visually identifying the dies, the results of the visual inspection can not be combined with the results of the electric tests because one is a paper-based system and the other one is computer-based. Transferring the information recorded on paper to a computer system costs a lot of time and slows down the inspecting rate. Furthermore, the inspection data is recorded by hand, and errors may occur occasionally, which reduces the inspection's precision.

Therefore, the inventor proposes the present invention to overcome the above problems based on his expert experience and deliberate research.

### SUMMARY OF THE INVENTION

The primary object of the present invention is to provide a wafer testing method and inspection system that records the inspection result in an electronic map file so that the inspection time is reduced.

Another object of the present invention is to provide a wafer testing method. The system is provided for recording the inspecting result on the electric map file. The occasions of artificial mistakes will be reduced.

In order to achieve the above objects, the present invention provides a wafer testing method comprising: (a) loading a wafer; (b) aligning the wafer with a map file image, wherein the map file is a first file type and comprises information of the wafer; (c) inspecting the appearance of the wafer; (d) if the wafer is identified as rejected, recording the inspection result for the wafer in the map file; and (e) saving the modified map file.

The operator performs visual inspection of each die and records the defects of the dies in the map file. Therefore, the examining rate is improved.

Moreover, the map file can be outputted as different file types so that the wafer testing system according to the present invention can be used in various systems.

In order to better understand the characteristics and technical contents of the present invention, a detailed description thereof will be made with reference to the accompanying drawings. However, it should be understood that the drawings and the description are illustrative and not to be used to limit the scope of the present invention.

### BRIEF DESCRIPTION OF THE DRAWINGS

FIG. 1 is a flow chart of the wafer inspection procedure according to the present invention.

FIG. 2 is a schematic view of the wafer testing system according to the present invention.

FIG. 3 is a schematic view of a wafer.

FIG. 4A is a schematic view showing the map file image with the result of electric tests.

FIG. 4B is a schematic view showing the modified map file image according to the present invention.

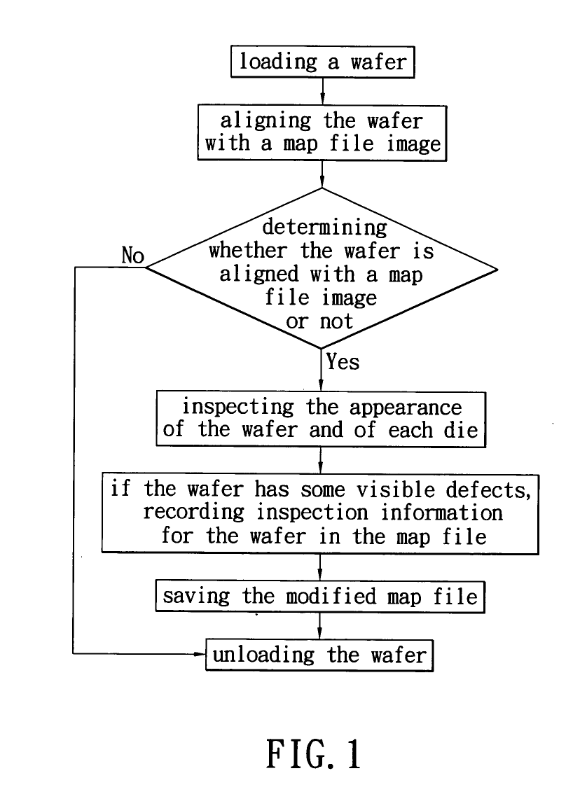

### DETAILED DESCRIPTION OF THE INVENTION

After the final step of manufacturing the integral circuit (IC) on the wafer, the wafer requires to be sorted into a plurality of single dies so that the packaging process can proceed on each die. However, before packaging the electric functions of each die have to be tested. Testing probes generally test each die and categorize the result of each tested die to output an electronic map file with a specific file type. In the preferred embodiment, the outputted map file is named as a map file with a first file type. The wafer testing system in the present invention also provides for visual inspection of the wafer and for directly modifying and recording the map file according to the inspection result.

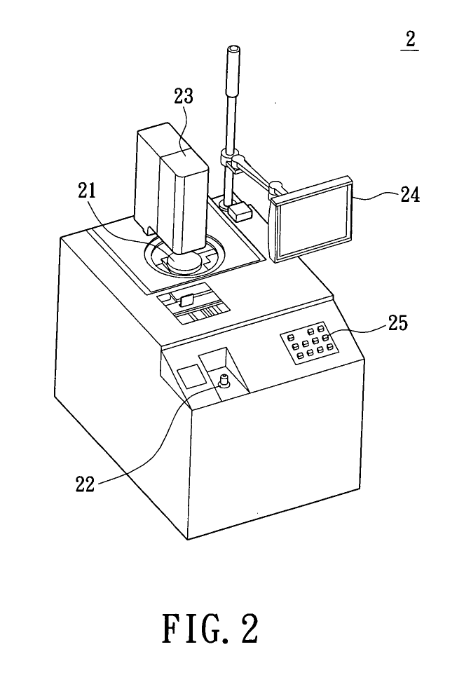

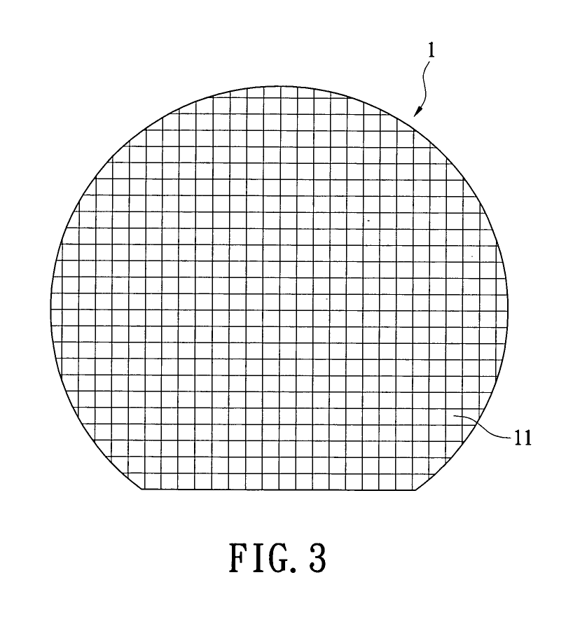

Please refer to FIG. 2. The invention discloses a wafer testing system 2, and the wafer testing system 2 can be used to visually inspect the appearance of the wafer 1. Further, the wafer testing system 2 is compatible with the map file of the first file type that is outputted after the electric function tests (E-test). In other words, the map file of the first file type is read by the wafer testing system 2. An operator first aligns the waver 1 with a map file image and efficiently records the inspection results in the map file and then saves it. As mentioned above, the result of the visual test can be digitized so as to improve the efficiency of the testing process. The wafer testing method of the wafer testing system 2 comprises the following steps (please refer to FIGS. 2-3):

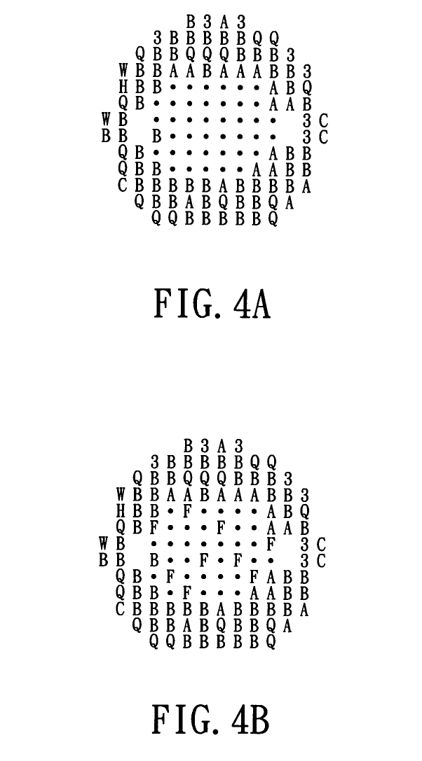

(a). A wafer 1 is provided and the wafer 1 has a plurality of dies thereon. The wafer 1 is disposed on a loading disk 21 and is loaded into the wafer testing system 2. Before loaded into the wafer testing system 2, the electric functions of each die 11 of the wafer 1 are tested via probes, such as memory test and logic test. “Bad” dies 11, who's electric functions are not in compliance with electric standards and which are identified as rejected, are inked by an inking process using a first color ink. Simultaneously, a map file is outputted for recording the result of the E-test. As shown in FIG. 4, a map file image is stored in the map file that contains the test result of each die 11. Numeric and alphabetical marks, i.e. A, B, Q and 3 represent the test result of each die 11 and the single dot is provided for a “good” die 11. The above marks are simply a reference for the embodiment and do not restrict the invention. Simply speaking, the wafer 1 is loaded into the wafer testing system 2 via the loading disk 21 and the map file containing the E-test information corresponding to the wafer 1 is also loaded to the wafer testing system 2.

By moving the loading disk 21, the wafer 1 is positioned below an image capturing device 23. The image capturing device 23 can be a charge-coupled device (CCD) or another image device that is familiar to those in the art. The wafer testing system 2 includes the image capturing device 23 so as to capture images of the wafer 1 on display device 24.

Step (b) is aligning the wafer 1 with the map file image. This step is necessary to enable an operator to mark the information for each die 1 at the right position of the map file. This step comprises some procedures. First, the wafer 1 is positioned on an orientation platform movable in three dimensions. Next steps are searching a top edge, a bottom edge, a left edge and a right edge of the wafer 1. The step of searching the top edge of the wafer 1 contains a searching process for the center of the top edge of the wafer. Depending on the positions of the top edge, the center of the top edge, a bottom edge, a left edge and a right edge of the wafer 1, the shape and the size of the wafer 1 are precisely determined. Following the step of determining the shape and the size of the wafer 1, the axes of the wafer 1 can be aligned with the axes of the image stored in the map file containing information for wafer 1. When an operator visually detects a “bad” die 11, having for example a surface defect, the position of the bad die 11 will be marked on the map file.

If shape and size of the wafer 1 cannot be aligned with the map file image, the wafer 1 will be unloaded. This situation may occur when the loaded wafer 1 is not suitable for the map file. In this case another wafer 1 must be loaded to continue the inspecting process.

Step (c) is inspecting the appearance of wafer 1. The image of wafer 1 is displayed on the display device 24 by the image capturing device 23. The image capturing device 23 further includes a zooming device. The operator can get a zoom-in image of the wafer 1 to clearly inspect its appearance. By controlling the moving device 22 of the wafer testing system 2, the wafer 1 can be moved with respect to the image capturing device 23 so that the operator can inspect the wafer 1 line by line and carefully observe its surface.

If defects are detected on wafer 1, step (d) is proceeded. In step (d) the positions of the defects are recorded and marked in the map file image. When the operator observes a scratch on the wafer, the positions of the ends of the scratch are recorded in the map file image. Please refer to FIG. 4A. The die 11 located at the fifth column from the right edge of wafer 1 and the fifth row from the bottom edge of the wafer 1 has passed the E-test, and the position of the die is marked by a single dot on the map file. Alternatively, when the operator inspects a defect on die 11, the operator can directly marked another symbol on the position of the map file using the inputting device 25. For example, the die 11 is marked by “F” in FIG. 4B compared to the single dot on FIG. 4A. Similarly, there are many dies 11 marked by a single dot in FIG. 4A, which are remarked by “F” in FIG. 4B reflecting the visual inspection results for these dies.

The wafer testing system 2 further has an inking system so that the operator can ink a second color on the dies 11 that have defects thereon. The second color is preferably different from the first color used in the E-test. Therefore, the test results are clearly classified on each die in E-test results or visual-inspection results.

The wafer testing system 2 is further provided for calculating the area or the length of the defects. For example, the area of the length of the scratch is calculated according to the positions of the ends of the scratch.

Step (d) also provides for saving the modified map file. When the operator has inspected each die 11 of the wafer 1 and marked “bad dies” on the map file, the map file is saved. The inspection results are recorded and marked as FIG. 4B. The modified map file is then saved with the first file type, i.e. the same file type as the map file after the E-test, and replaces the original map file. Alternatively, the modified map file is saved as a second file type. In other words, the modified map file is outputted as a new map file.

For protecting the wafer 1, the wafer testing system 2 further has an automatic robotic manipulator for loading and unloading the wafer 1.

To sum up, the present invention achieves the following advantages:
1. The wafer testing system 2 has a higher testing rate compared to the prior art. The operator can directly mark and modify the map file on the computer system. The time for transforming the traditional paper work into electronic files can be saved.
2. The wafer testing system 2 can read the map file and align the map file image with the wafer 1, so that positions of the dies 11 are clearly related to the map file. Therefore, occurrences of erroneous marking are prevented.
3. The present invention is suitable for an automatic production line, and the production rate and throughput rate are improved.

Although the present invention has been described with reference to the foregoing preferred embodiment, it will be understood that the invention is not limited to the details thereof. Various equivalent variations and modifications may occur to those skilled in this art in view of the teachings of the present invention. Thus, all such variations and equivalent modifications are embraced within the scope of the invention as defined in the appended claims.

What is claimed is:

1. A wafer testing method, comprising:
(a) loading a wafer;
(b) aligning the wafer with a map file image, wherein the map file image is stored in a map file, and the map file is of a first file type and comprises information of the wafer;
(c) inspecting an appearance of the wafer;
(d) if the wafer is identified as rejected, recording inspection information of the wafer in the map file; and
(e) saving the modified map file.

2. The wafer testing method according to claim 1, wherein step (b) further comprises a step of positioning the wafer and searching a top edge, a bottom edge, a left edge and a right edge of the wafer.

3. The wafer testing method according to claim 2, wherein in the step of searching the top edge of the wafer further comprises a step of searching a center of the top edge of the wafer.

4. The wafer testing method according to claim 3, wherein step (b) further comprises a step of determining a shape of the wafer and aligning the shape of the wafer with axes of the map file image.

5. The wafer testing method according to claim 4, wherein in step (c) the wafer is unloaded if the shape of the wafer does not match with the axes of the map file image.

6. The wafer testing method according to claim 1, wherein the wafer comprises a plurality of dies.

7. The wafer testing method according to claim 6, wherein step (c) comprises a step of moving the wafer repeatedly and inspecting the appearance of each die.

8. The wafer testing method according to claim 7, wherein step (d) further comprises a step of remarking a position on the map file image corresponding to a die if the respective die has been identified as rejected.

9. The wafer testing method according to claim 1, wherein in step (d) if a scratch has been detected on the wafer positions of ends of the scratch are recorded in the map file image.

10. The wafer testing method according to claim 9, wherein step (d) further comprises a step of calculating an area and a length of the scratch according to the positions of the ends of the scratch recorded in the map file.

11. The wafer testing method according to claim 1, wherein in step (e) the modified map file is saved as the first file type.

12. The wafer testing method according to claim 1, wherein in step (e) the modified map file is saved as a second file type.

13. The wafer testing method according to claim 1, further comprising a step of unloading the wafer following step (e).
